(19) United States
(12) Patent Application Publication
(10) Pub. No.: US 2020/0097623 A1
(43) Pub. Date: Mar. 26, 2020

(54) PRODUCTION SYSTEM TO MODEL AND ANALYZE A MANUFACTURING PROCESS

(71) Applicant: THE BOEING COMPANY, Chicago, IL (US)

(72) Inventors: John R. Palmer, Seattle, WA (US); William M. Harper, Renton, WA (US); Hung L. Nguyen, Seattle, WA (US); Navin B. Johnson, Bothell, WA (US); Joseph R. Twardoski, Mill Creek, WA (US); Thomas P. Harper, Mukilteo, WA (US); Joseph R. Cabotaje, Seattle, WA (US); Anna Fe J. Garcia, Mukilteo, WA (US)

(73) Assignee: The Boeing Company

(21) Appl. No.: 16/142,363

(22) Filed: Sep. 26, 2018

(51) Int. Cl. G06F 17/50; G06Q 10/06; G06Q 50/04

(52) U.S. Cl. CPC G06F 17/5009; G06Q 10/067; G06Q 50/04; G06Q 10/06313

(57) ABSTRACT

A computing device is configured to form a data structure modeling a production system. The data structure includes a plurality of process node data elements corresponding to production tasks of a manufacturing process described by the production system. Responsive to input, the computing device stores linking data to link process node data elements to objects that describe characteristics associated with process specifications, manufacturing devices, and other process characteristics. The computing device is also configured to update a set of production system estimates associated with the manufacturing process based on objects, and to compare the set of production system estimates to an acceptance criterion for the production system. The computer device also generates a notification indicating whether the manufacturing process described by the production system is expected to satisfy requirements indicated by the acceptance criterion.

### FIELD OF THE DISCLOSURE

The present disclosure is generally related to modelling a manufacturing process.

### BACKGROUND

Modern manufacturing processes can include multiple tasks, including manual and automated task, performed using a variety of different tools and equipment and involving many sequential and/or parallel operations. As a non-limiting example, a manufacturing process for constructing an aircraft wing can include a plurality of different task that are performed by different personnel, tools, materials, etc.

Due in part to this complexity, adding manufacturing processes or modifying existing processes can be quite complicated. For example, a new process might use a tool that is not used elsewhere in the manufacturing process, in which case new equipment or tooling may need to be acquired to use the new process. Also, the new process needs to integrate with other processes in the manufacturing operation. To illustrate, if a component produced by the new process is not exactly identical to a component manufactured by a process that is being replaced, consideration should be given to whether the component produced by the new process is compatible with other steps in the manufacturing process. Likewise, consideration should be given to whether the new process can use input materials (e.g., partial components or subassemblies) produced by an upstream process. For very large scale, dynamic manufacturing, such as aircraft manufacturing and system integration, a change to a single process or process step can have far-reaching upstream and downstream effects.

Prior to performance of the manufacturing process, it can be difficult to determine whether the manufacturing process will satisfy the relevant manufacturing criteria. For example, it may be difficult to determine whether the total cost of performing the manufacturing process will be equal to or less than a budget target, it may be difficult to determine whether the total amount of labor time for different personnel (or a particular personnel member) will be equal to or less than a labor budget, etc. Similarly, it can be difficult to compare different options to see which is preferable.

Manufacturing processes can be modeled to attempt to identify incompatibility issues, for budgeting purposes, for planning purposes (e.g., to ensure that personnel, equipment, and materials are available), and for other reasons. However, modeling manufacturing processes is difficult and time consuming, and changes to the manufacturing process or modeling a new manufacturing process may require replicating data that was used to model the original manufacturing process. As a result, modeling different manufacturing processes can utilize a relatively large amount of memory.

### SUMMARY

In a particular aspect, a computing device includes one or more processors and one or more memory devices. The one or more memory devices store a data structure of a production system. The data structure includes a plurality of process node data elements, each process node data element corresponding to one or more production tasks of a manufacturing process described by the production system. The one or more memory devices store a plurality of process object libraries, including a process specification object library, an equipment object library, one or more additional object libraries, and instructions. The process specification object library includes a plurality of process specification objects, each process specification object of the plurality of process specification objects describing characteristics associated with a respective process specification. The equipment object library includes a plurality of equipment objects, each equipment object of the plurality of equipment objects describing equipment-related characteristics associated with a respective manufacturing equipment item. The one or more additional object libraries each include one or more additional objects. The instructions are executable by the one or more processors to cause the one or more processors to perform operations. The operations include receiving a first input associating a first production task with a first process specification object of the plurality of process specification objects, where the first process specification object describes first process characteristics associated with a first process specification. The operations also include, responsive to the first input, storing first linking data linking a first process node data element of the plurality of process node data elements to the first process specification object, where the first process node data element is associated with the first production task. The operations also include receiving a second input associating the first production task with a first equipment object of the plurality of equipment objects, where the first equipment object describes first equipment-related manufacturing process characteristics associated with a first manufacturing device. The operations further include, responsive to the second input, storing second linking data linking the first process node data element to the first equipment object. The operations also include receiving third input associating the first production task with one or more additional process objects from the one or more additional process object libraries, where each process object of the one or more additional process objects describes one or more process characteristics. The operations further include, responsive to the third input, storing third linking data linking the first process node data element to the one or more additional process objects. The operations also include updating a set of production system estimates associated with the manufacturing process based on objects linked to the first process node data element, and comparing the set of production system estimates to an acceptance criterion for the production system. The operations further include generating a notification indicating whether the manufacturing process described by the production system is expected to satisfy requirements indicated by the acceptance criterion.

In a particular implementation, a method includes accessing, by a processor of a computing device, a data structure corresponding to a production system. The data structure includes a plurality of process node data elements, and each process node data element corresponds to one or more production tasks of a manufacturing process described by the production system. The method also includes receiving, at the processor, first input associating a first production task with a first process specification object of a plurality of process specification objects in a process specification object library. Each process specification object of the plurality of process specification objects describes process characteristics associated with a respective process specification, and the first process specification object describes first process characteristics associated with a first process specification. The method includes, responsive to the first input, storing first linking data linking a first process node data element to the first process specification object, where the first process node data element is associated with the first production task. The method further includes receiving, at the processor, second input associating the first production task with a first equipment object of a plurality of equipment objects in an equipment object library, where the first equipment object describes first equipment-related manufacturing process characteristics associated with a first manufacturing device. The method also includes, responsive to the second input, storing second linking data linking the first process node data element to the first equipment object. The method further includes receiving, at the processor, third input associating the first production task with one or more additional process objects from the one or more additional process object libraries. Each process object of the one or more additional process objects describes one or more process characteristics. The method also includes responsive to the third input, storing third linking data linking the first process node data element to the one or more additional process objects. The method includes updating a set of production system estimates of the data structure based on objects linked to the first process node data element and comparing the set of production system estimates to an acceptance criterion for the production system. The method further includes generating a notification indicating whether the manufacturing process described by the production system is expected to satisfy requirements indicated by the acceptance criterion.

A non-transitory computer-readable storage device storing instructions that are executable by a processor to cause the processor to perform operations including accessing a data structure corresponding to a production system. The data structure includes a plurality of process node data elements, where each process node data element corresponds to one or more production tasks of a manufacturing process described by the production system. The operations also include receiving first input associating a first production task with a first process specification object of a plurality of process specification objects in a process specification object library. Each process specification object of the plurality of process specification objects describes process characteristics associated with a respective process specification, and the first process specification object describes first process characteristics associated with a first process specification. The operations further include, responsive to the first input, storing first linking data linking a first process node data element to the first process specification object, where the first process node data element is associated with the first production task. The operations also include receiving second input associating the first production task with a first equipment object of a plurality of equipment objects in an equipment object library, where the first equipment object describes first equipment-related manufacturing process characteristics associated with a first manufacturing device. The operations also include, responsive to the second input, storing second linking data linking the first process node data element to the first equipment object. The operations include receiving third input associating the first production task with one or more additional process objects from one or more additional process object libraries. Each process object of the one or more additional process objects describes one or more process characteristics. The operations further include, responsive to the third input, storing third linking data linking the first process node data element to the one or more additional process objects. The operations also include updating a set of production system estimates of the data structure based on objects linked to the first process node data element and comparing the set of production system estimates to an acceptance criterion for the production system. The operations also include generating a notification indicating whether the manufacturing process described by the production system is expected to satisfy requirements indicated by the acceptance criterion.

### BRIEF DESCRIPTION OF THE DRAWINGS

FIG. 1 is a diagram that illustrates aspects of an example of a system to model a manufacturing process.

FIG. 2 is a diagram that illustrates aspects of the system of FIG. 1.

FIG. 3 is a diagram that illustrates linking an object to a first node data element and generating production system estimates based on the link.

FIG. 4 is a diagram that illustrates linking another object to the first node data element and updating the production system estimates based on the link.

FIG. 5 is a diagram that illustrates linking another object to the first node data element and updating the production system estimates based on the link.

FIG. 6 is a diagram that illustrates linking another object to the first node data element and updating the production system estimates based on the link.

FIG. 7 is a diagram that illustrates linking another object to the first node data element and updating the production system estimates based on the link.

FIG. 8 is a diagram that illustrates linking another object to a second node data element and updating production system estimates based on the link.

FIG. 9 is a diagram that illustrates aspects of the system of FIG. 1.

FIG. 10A is a flow chart of an example of a method of modeling a manufacturing process.

FIG. 10B is a flow chart of another example of a method of modeling a manufacturing process.

FIG. 11 is a block diagram illustrating aspects of an example of a computing system configured to perform operations to model a manufacturing process.

### DETAILED DESCRIPTION

Various aspects described herein enable modeling a manufacturing process. For example, a computing device generates a production system that models the manufacturing process by linking node data elements of the production system to a plurality of objects in object libraries. The computing device generates and stores a data structure that includes process node data elements. The process node data elements include linking data that indicates which node data elements are linked to which objects. The data structure enables the computing device to generate production system estimates that can be used to evaluate the manufacturing process. For example, the production system estimates can be compared to acceptance criteria, such as technical readiness criteria, environmental and safety criteria, costs, input and/or output materials, and so forth. The object libraries provide a reusable mechanism to model many different manufacturing processes in a manner that is resource efficient. For example, using reusable object libraries to generate the data structure means that the content of the libraries does not need to be replicated each time a new manufacturing process is modeled, or when a change to the manufacturing process is proposed. Thus, using the object libraries and linking data uses less memory than a system in which the content of the objects is replicated for each new or modified manufacturing system.

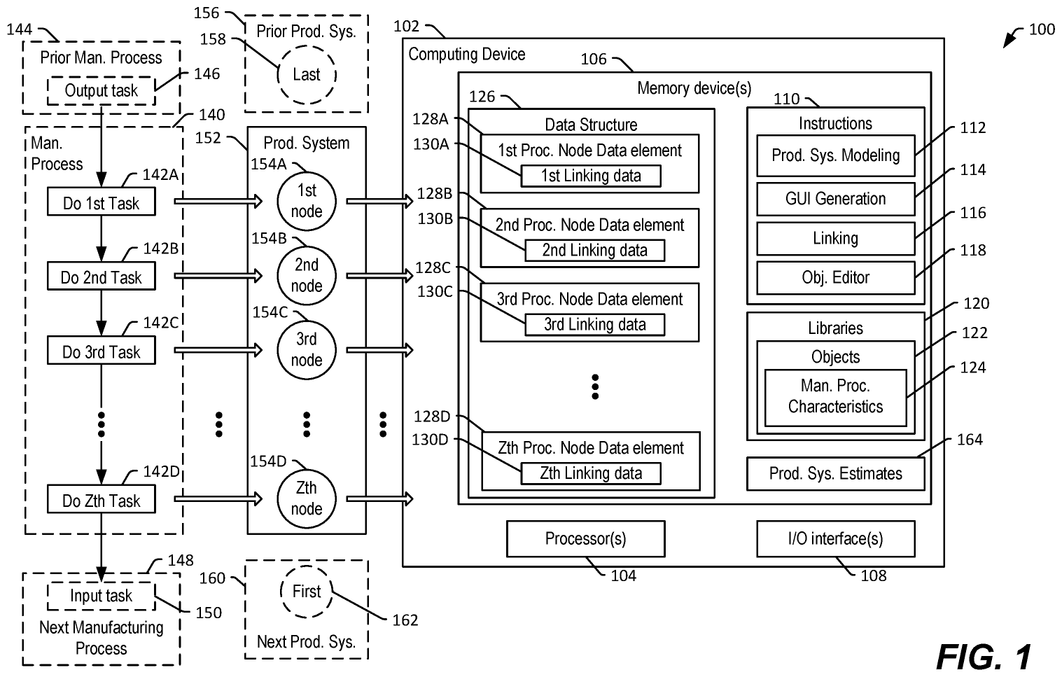

Particular implementations are described herein with reference to the drawings. In the description, common features are designated by common reference numbers throughout the drawings. In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple nodes of a production system 152 are illustrated and associated with reference numbers 154A, 154B, 154C, and 154D. When referring to a particular one of these nodes, such as a first node 154A, a distinguishing letter (e.g., “A”) is used. However, when referring to any arbitrary one of these nodes or to the nodes as a group, the reference number 154 is used without a distinguishing letter.

As used herein, various terminology is used for the purpose of describing particular implementations only and is not intended to be limiting. For example, the singular forms “a,” “an,” and “the” are intended to include the plural forms as well, unless the context clearly indicates otherwise. Further, the terms “comprise,” “comprises,” and “comprising” are used interchangeably with “include,” “includes,” or “including.” Additionally, the term “wherein” is used interchangeably with the term “where.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to a grouping of one or more elements, and the term “plurality” refers to multiple elements.

As used herein, “generating”, “calculating”, “using”, “selecting”, “accessing”, and “determining” are interchangeable unless context indicates otherwise. For example, “generating”, “calculating”, or “determining” a value (or a signal) can refer to actively generating, calculating, or determining the value (or the signal) or can refer to using, selecting, or accessing the value (or the signal) that is already generated, such as by another component or device. Additionally, “adjusting” and “modifying” can be used interchangeably. For example, “adjusting” or “modifying” a parameter can refer to changing the parameter from a first value to a second value (a “modified value” or an “adjusted value”). As used herein, “coupled” can include “communicatively coupled,” “electrically coupled,” or “physically coupled,” and can also (or alternatively) include any combinations thereof. Two devices (or components) can be coupled (e.g., communicatively coupled, electrically coupled, or physically coupled) directly or indirectly via one or more other devices, components, wires, buses, networks (e.g., a wired network, a wireless network, or a combination thereof), etc. Two devices (or components) that are electrically coupled can be included in the same device or in different devices and can be connected via electronics, one or more connectors, or inductive coupling, as illustrative, non-limiting examples. In some implementations, two devices (or components) that are communicatively coupled, such as in electrical communication, can send and receive electrical signals (digital signals or analog signals) directly or indirectly, such as via one or more wires, buses, networks, etc. As used herein, “directly coupled” is used to describe two devices that are coupled (e.g., communicatively coupled, electrically coupled, or physically coupled) without intervening components.

FIG. 1 is a diagram that illustrates aspects of an example of a system 100 to model a manufacturing process 140. The system 100 includes a computing device 102 that is configured to generate a production system 152 that models the manufacturing process 140 by linking node data elements 154 of the production system 152 to a plurality of objects 122 in object libraries 120. The computing device 102 generates and stores a data structure 126 that includes process node data elements 128. The process node data elements 128 include linking data 130 that indicates which node data elements 154 are linked to which objects 122. The data structure 126 enables the computing device 102 to generate production system estimates 164 that can be used to evaluate the manufacturing process 140. For example, the production system estimates 164 can be compared to acceptance criteria, such as technical readiness criteria, environmental and safety criteria, costs, input and/or output materials, and so forth. The object libraries 120 provide a reusable mechanism to model many different manufacturing processes in a manner that is resource efficient. For example, using reusable object libraries 120 to generate the data structure 126 means that the content of the libraries does not need to be replicated each time a new manufacturing process is modeled, or when a change to the manufacturing process 140 is proposed. Thus, using the object libraries 120 and linking data 130 uses less memory than a system in which the content of the objects 122 is replicated for each new or modified manufacturing system.

The computing device 102 includes one or more processors 104 and one or more memory devices 106. The computing device 102 also includes input/output interfaces 108 to enable user interaction with the computing device 102. As a non-limiting example, an input interface of the input/output interfaces 108 can receive a user command to generate the production system estimates 164. As another non-limiting example, an output interface of the input/output interfaces 108 can provide a visual display of the production system estimates 164 to a display screen. For example, instructions 110 stored at the one or more memory devices 106 can include graphical user interface generation instructions 114. The one or more processors 104 can execute the graphical user interface generations instructions 114 to display the production system estimates 164 at the display screen using the output interface of the input/output interfaces 108.

The manufacturing process 140 can include one process in a large scale manufacturing and integration operation, such as a process for manufacturing aircraft components and integrating the components to form an aircraft. As a non-limiting example, the manufacturing process 140 can include a process for manufacturing an aircraft wing, an aircraft landing gear, an aircraft nose gear, an elevator, an aircraft vertical stabilizer, an aircraft rudder, etc. The manufacturing process 140 includes a plurality of production tasks 142. For example, the manufacturing process 140 includes a first production task 142A, a second production task 142B, a third production task 142C, and a Zth production task 142D (where Z is a positive integer greater than three). Although four production tasks 142 are illustrated, in other implementations, the manufacturing process 140 can include additional (or fewer) production tasks. The production tasks 142 can be ordered sequentially in the manufacturing process 140. For example, the second production task 142B can follow the first production task 142A, the third production task 142C can follow the second production task 142B, etc. In some implementations, two or more of the production tasks 142 can be parallel in the manufacturing process 140. For example, the second production task 142B and the first production task 142A can be performed simultaneously or concurrently. In some implementations, the order of two or more of the production tasks 142 can be inconsequential in the manufacturing process 140. For example, the second production task 142B and the first production task 142A can be performed in any order. In some implementations, some or all of the production tasks 142 can be conditional. For example, the second production task 142B can be performed if the first production task 142A satisfies particular criteria. Some implementations can include production tasks 142 that are arranged according to more than one of the above, such as two or more sequential productions tasks 142, two or more parallel production tasks 142, one or more production tasks 142 that can be performed without regard to sequence, one or more conditional production tasks 142, or a combination thereof. Performance of each production task 142 can use one or more resources, such as tools, equipment, personnel, etc. As described below, the objects 122 in the object libraries 120 are used to model the resources that are anticipated for each production task 142.

In FIG. 1, a prior manufacturing process 144 is also illustrated. The prior manufacturing process 144 is performed prior to the manufacturing process 140. For example, in a sequential arrangement, an output task 146 (e.g., a final task, corresponding to a last node data element 158) of the prior manufacturing process 144 is performed prior to the first production task 142A of the manufacturing process 140. The manufacturing process 140 uses an output of the prior manufacturing process 144. For example, the manufacturing process 140 can further process a partial component generated by the prior manufacturing process 144, or can combine a subassembly generated by the prior manufacturing process 144 to generate an assembly. Although only one prior manufacturing process 144 is illustrated in FIG. 1, the manufacturing process 140 can be associated with more than one prior manufacturing process 144.

Additionally, in FIG. 1, a next manufacturing process 148 is illustrated. In a sequential arrangement, the next manufacturing process 148 is performed after the manufacturing process 140. For example, an input task 150 (e.g., a first task, corresponding to a first node data element 162) of the next manufacturing process 148 can be performed after the Zth production task 142D of the manufacturing process 140. The next manufacturing process 148 uses an output of the manufacturing process 140. For example, the next manufacturing process 148 can further process a partial component generated by the manufacturing process 140 or can combine a subassembly generated by the manufacturing process 140 to generate an assembly. Although only one next manufacturing process 148 is illustrated in FIG. 1, the manufacturing process 140 can be associated with more than one next manufacturing process 148.

The computing device 102 generates the production system 152 to model the manufacturing process 140. To illustrate, the instructions 110 include production system modeling instructions 112 that are executable by the one or more processors 104 to generate the production system 152 that models the manufacturing process 140 based on user input. Upon execution of the production system modeling instructions 112, the one or more processors 104 generate a first node data element 154A of the production system 152 that corresponds to the first production task 142A, a second node data element 154B of the production system 152 that corresponds to the second production task 142B, a third node data element 154C of the production system 152 that corresponds to the third production task 142C, and a Zth node data element 154D of the production system 152 that corresponds to the Zth production task 142D. The prior production system 156 and the next production system 160 can be modeled in a similar manner.

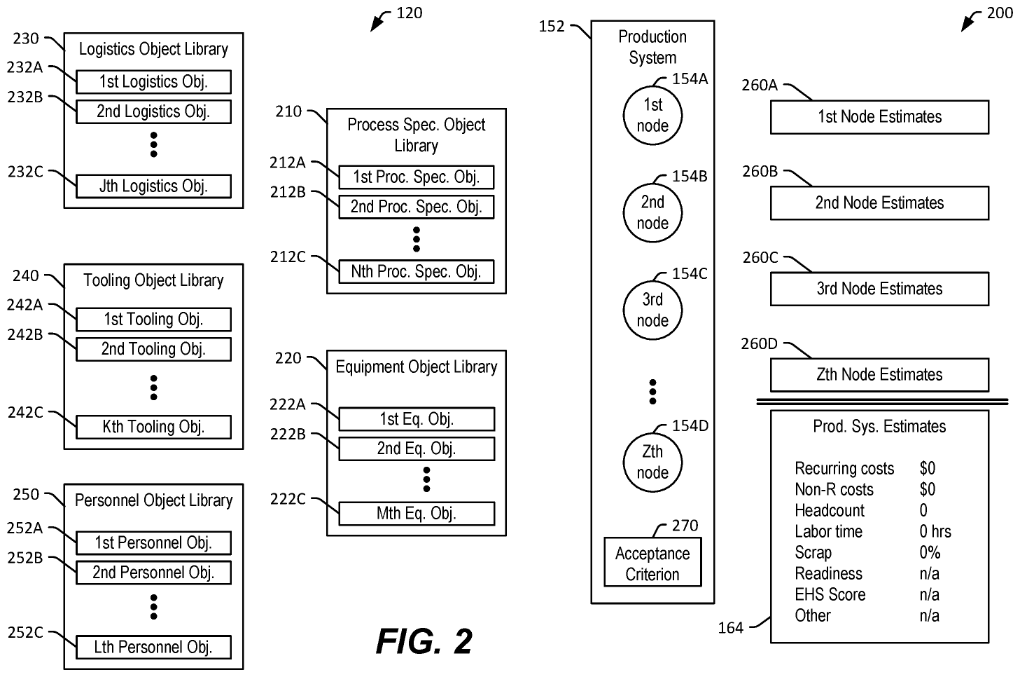

The computing device 102 links each node data element 154 of the production system 152 to particular objects 122 (in the object libraries 120) that correspond to resources for performing the corresponding production task 142. For example, linking instructions 116 (included in the instructions 110) can be executed by the one or more processors 104 to link each of the node data elements 154 to the particular objects 122 that correspond to resources for performing the corresponding production task 142. As described below, the links are used to generate the production system estimates 164 that are used to evaluate the manufacturing process 140. The linking process is described in greater detail with respect to FIGS. 2-9.

As each node data element 154 is linked to different objects, the one or more processors 104 generate (or update) linking data 130 associated with a corresponding process node data element 128 in the data structure 126. To illustrate, the one or more processors 104 generate the data structure 126 and store the data structure 126 at the one or more memory devices 106. In the example illustrated in FIG. 1, the data structure 126 includes a first process node data element 128A that includes first linking data 130A. The first linking data 130A indicates which objects 122 are linked to the first node data element 154A based on manufacturing process characteristics 124 associated with the first production task 142A. As different objects 122 are linked to (or unlinked from) the first node data element 154A, the one or more processors 104 update the first linking data 130A to reflect the changes. The data structure 126 also includes a second process node data element 128B that includes second linking data 130B. The second linking data 130B indicates which objects 122 are linked to the second node data element 154B based on manufacturing process characteristics 124 associated with the second production task 142B. As different objects 122 are linked to (or unlinked from) the second node data element 154B, the one or more processors 104 update the second linking data 130B to reflect the changes.

The data structure 126 also includes a third process node data element 128C that includes third linking data 130C. The third linking data 130C indicates which objects 122 are linked to the third node data element 154C based on manufacturing process characteristics 124 associated with the third production task 142C. As different objects 122 are linked to (or unlinked from) the third node data element 154C, the one or more processors 104 update the third linking data 130C to reflect the changes.

The data structure 126 also includes a Zth process node data element 128D that includes Zth linking data 130D. The Zth linking data 130D indicates which objects 122 are linked to the Zth node data element 154D based on manufacturing process characteristics 124 associated with the Zth production task 142D. As different objects 122 are linked to (or unlinked from) the Zth node data element 154D, the one or more processors 104 update the Zth linking data 130D to reflect the changes.

According to one implementation, the plurality of process node data elements 128 are linked according to a precedence order, a criteria-driven branching order, a parallel branching order, a criteria-driven merge order, a parallel merge order, a repeated operations order, or a combination thereof.

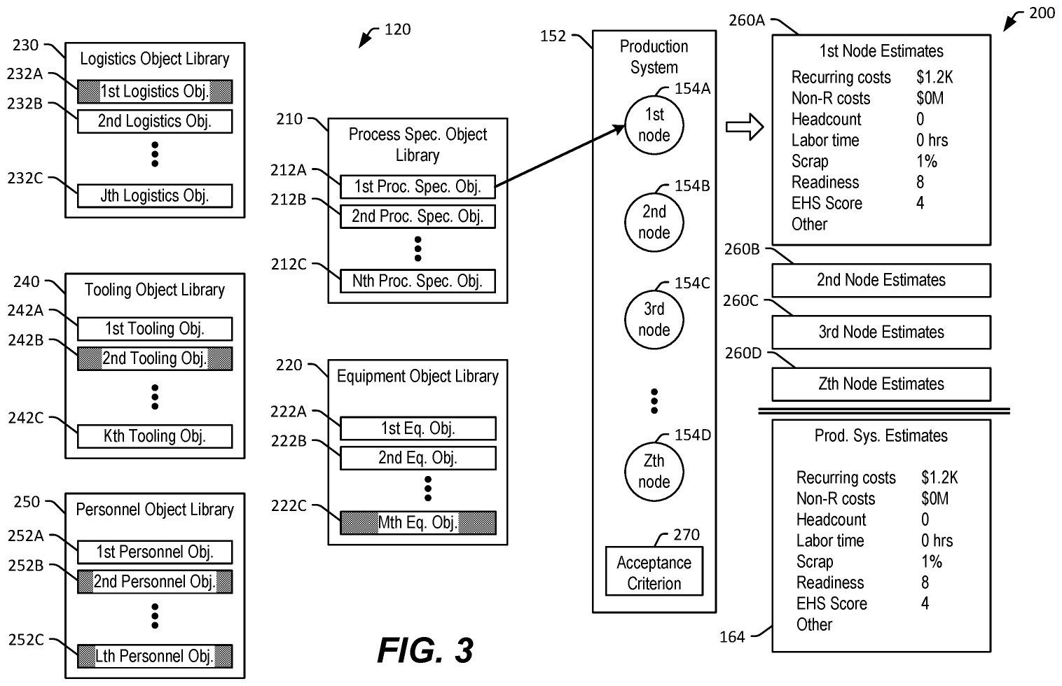

As described in greater detail with respect to FIGS. 3-9, object editor instructions 118 are also executable by the one or more processors 104 to edit selections of the objects 122. For example, if a first object 122 is selected that described particular object characteristics, the one or more processors 104 can execute the object editor instructions 118 to identify other objects 122 that satisfy the particular object characteristics and to inhibit selection of objects 122 that do not satisfy the particular object characteristics.

The one or more processors 104 update the production system estimates 164 based on the linking data 130. For example, because the linking data 130 indicates the objects 122 (e.g., the resources) to be used during the manufacturing process 140, the one or more processors 104 can update the production system estimates 164 (e.g., costs, labor time, readiness, and other factors associated with performing the manufacturing process 140) based on the objects 122.

The system 100 of FIG. 1 enables the computing device 102 to efficiently generate the production system estimates 164 for the manufacturing process 140 and compare the production system estimates 164 to acceptance criteria. For example, the production system estimates 164 can be compared to technical readiness criteria, environmental and safety criteria, costs, input and/or output materials, and so forth. The object libraries 120 provide a reusable mechanism to model many different manufacturing processes, such as the manufacturing process 140, in a manner that is resource efficient. For example, using reusable object libraries 120 to generate the data structure 126 means that the content of the libraries 120 does not need to be replicated each time a new manufacturing process is modeled, or when a change to the manufacturing process 140 is proposed. Thus, using the object libraries 120 and linking data 130 uses less memory than a system in which the content of the objects 122 is replicated for each new or modified manufacturing system.

FIG. 2 is a diagram 200 that illustrates aspects of the system of FIG. 1. The diagram 200 includes the object libraries 120, the production system 152, node estimates 260, and the production system estimates 164. The object libraries 120 include a process specification object library 210, an equipment object library 220, a logistics object library 230, a tooling object library 240, and a personnel object library 250.

The process specification object library 210 includes a plurality of process specification objects 212. For example, the process specification object library 210 includes a first process specification object 212A, a second process specification object 212B, and an Nth process specification object 212C (where N is a positive integer greater than two). Although three process specification objects 212 are illustrated, in other implementations, the process specification object library 210 can include additional (or fewer) process specification objects. Each process specification object 212 describes characteristics associated with a respective process specification. For example, each process specification object 212 can describe the amount of time predicted to perform a corresponding production task 142 of the manufacturing process 140, the predicted amount of overhead to perform the corresponding production task 142, etc.

The equipment object library 220 includes a plurality of equipment objects 222. For example, the equipment object library 220 includes a first equipment object 222A, a second equipment object 222B, and an Mth equipment object 222C (where M is a positive integer greater than two). Although three equipment objects 222 are illustrated, in other implementations, the equipment object library 220 can include additional (or fewer) equipment objects. Each equipment object 222 describes equipment-related characteristics associated with a respective manufacturing equipment item. For example, each equipment object 222 can describe what equipment to be used to perform a corresponding production task 142 of the manufacturing process 140, a cost of the equipment, etc.

The logistics object library 230 includes a plurality of logistics objects 232. For example, the logistics object library 230 includes a first logistics object 232A, a second logistics object 232B, and a Jth logistics object 232C (where J is a positive integer greater than two). Although three logistics objects 232 are illustrated, in other implementations, the logistics object library 230 can include additional (or fewer) equipment objects. Each logistics object 232 describes a set of logistics-related manufacturing process characteristics. For example, each logistics object 232 can describe materials or subassemblies used to perform the corresponding production task 142 of the manufacturing process 140.

The tooling object library 240 includes a plurality of tooling objects 242. For example, the tooling object library 240 includes a first tooling object 242A, a second tooling object 242B, and a Kth tooling object 242C (where K is a positive integer greater than two). Although three tooling objects 242 are illustrated, in other implementations, the tooling object library 240 can include additional (or fewer) tooling objects. Each tooling object 242 describes a set of tooling-related manufacturing process characteristics. For example, each tooling object 242 can describe what type (or types) of tools are to be used to perform a corresponding production task 142 of the manufacturing process 140, a cost of each tool, etc.

The personnel object library 250 includes a plurality of personnel objects 252. For example, the personnel object library 250 includes a first personnel object 252A, a second personnel object 252B, and an Lth personnel object 252C (where L is a positive integer greater than two). Although three personnel objects 252 are illustrated, in other implementations, the personnel object library 250 can include additional (or fewer) personnel objects. Each personnel object 252 describes a set of personnel-related manufacturing process characteristics. For example, each personnel object 252 can describe what type of workers (e.g., a worker skill set) should be used to perform a corresponding production task 142 of the manufacturing process 140, how many workers should be used to perform the corresponding production task 142, how long each worker will be working to perform the corresponding production task 142, etc.

In addition to the node data elements 154, the production system 152 also includes acceptance criterion 270. The acceptance criterion 270 can include technical readiness criteria, environmental and safety criteria, costs, input and/or output materials, and so forth. As described below, the production system estimates 164 can be compared to the acceptance criterion 270 to determine whether performance of the manufacturing process 140 can be achieved while satisfying the various acceptance criteria 270 or whether adjustments need to be made to the manufacturing process 140. In some scenarios, the acceptance criterion 270 for the production system 152 can be determined based on requirements data received by the one or more processors 104. The requirements data indicates a condition of assembly associated with the manufacturing process 140. For example, the condition of assembly indicates input materials for the manufacturing process 140 and an expected output product for the manufacturing process 140.

As each node data element 154 is linked to different objects in the object libraries 120, corresponding node estimates 260 are updated. For example, as objects in the object libraries 120 are linked to the first node data element 154A, first node estimates 260A are updated based on the linked objects 122. The first node estimates 260A, the second node estimates 260B, the third node estimates 260C, and the Zth node estimates 260D can include recurring costs estimates, non-recurring costs estimates, headcount estimates, labor time estimates, scrap estimates, readiness estimates, environmental, health, and safety (EHS) scores, and other estimates. In a similar manner, as objects 122 in the object libraries 120 are linked to the other node data elements 154B-154D, the respective node estimates 260B-260D are updated based on the linked objects 122. The production system estimates 164 are equal to the sum of the node estimates 260A-260D.

The production system estimates 164 can be compared to the acceptance criterion 270 (e.g., technical readiness criteria, environmental and safety criteria, costs, input and/or output materials, and so forth). For example, the production system estimates 164 can include an estimated one-time cost (e.g., a non-recurring cost) of the manufacturing process 140, and the acceptance criterion 270 can include a one-time cost threshold. The one-time cost can be compared to the one-time cost threshold to determine whether to make adjustments to the manufacturing process 140. As another example, the production system estimates 164 can include an estimated recurring cost of the manufacturing process 140, and the acceptance criterion 270 can include a recurring cost threshold. The estimated recurring cost can be compared to the recurring cost threshold to determine whether to make adjustments to the manufacturing process 140. As another example, the production system estimates 164 can include an environmental, health, and safety (EHS) score, and the acceptance criterion 270 can include an EHS score threshold. The EHS score can be compared to the EHS score threshold to determine whether to make adjustments to the manufacturing process 140. As another example, the production system estimates 164 can include a manufacturing readiness score, and the acceptance criterion 270 can include a manufacturing readiness score threshold. The manufacturing readiness score can be compared to the manufacturing readiness score threshold to determine whether to make adjustments to the manufacturing process 140. As another example, the production system estimates 164 can include a manufacturing scrap estimate, and the acceptance criterion 270 can include a manufacturing scrap threshold. The manufacturing scrap estimate can be compared to the manufacturing scrap threshold to determine whether to make adjustments to the manufacturing process 140. As another example, the production system estimates 164 can include a headcount projection, and the acceptance criterion 270 can include a headcount threshold. The headcount projection can be compared to the headcount threshold to determine whether to make adjustments to the manufacturing process 140. As another example, the production system estimates 164 can include a labor time estimate, and the acceptance criterion 270 can include a labor time threshold. The labor time estimate can be compared to the labor time threshold to determine whether to make adjustments to the manufacturing process 140.

The object libraries 120 provide a reusable mechanism to model many different manufacturing processes, such as the manufacturing process 140 of FIG. 1, in a manner that is resource efficient. For example, using the reusable object libraries 120 to generate the data structure 126 of FIG. 1 means that the content of the libraries 120 does not need to be replicated each time a new manufacturing process is modeled, or when a change to the manufacturing process 140 is proposed. Thus, using the object libraries 120 and linking data uses less memory than a system in which the content of the objects 122 is replicated for each new or modified manufacturing system.

FIG. 3 is a diagram that illustrates linking an object to a first node data element and generating production system estimates based on the link. For example, in FIG. 3, the first process specification object 212A is linked to the first node data element 154A.

According to linking operation illustrated in FIG. 3 (and with reference to FIGS. 1 and 2), the input interface of the input/output interfaces 108 receives a first input that associates the first production task 142A with the first process specification object 212A. In response to receiving the first input, the one or more processors 104 link the first node data element 154A (e.g., the modeled version of the first production task 142A) to the first process specification object 212A that describes first process characteristics associated with a first specification. Additionally, the one or more processors 104 generate the first linking data 130A to indicate that the first node data element 154A is linked to the first process specification object 212A.

The first node estimates 260A are generated based on the first process specification object 212A. For example, the first node estimates 260A include a recurring cost of $1,200, a 1% manufacturing scrap estimate, a manufacturing readiness score of 8, and an EHS score of 4. Because there are no objects linked to the other node data elements 154B-154D, the other corresponding node estimates 260B-260D are null, and the production system estimates 164 are equal to the first node estimates 260A. For example, the production system estimates 164 include a recurring cost of $1,200, a 1% manufacturing scrap estimate, a manufacturing readiness score of 8, and an EHS score of 4.

The one or more processors 104 can execute the object editor instructions 118 to identify a set of objects that satisfy the first process characteristics described by the first process specification object 212A. For example, the one or more processors 104 can identify the first equipment object 222A, the second equipment object 222B, the second logistics object 232B, the Jth logistics object 232C, the first tooling object 242A, the Kth tooling object 242C, and the first personnel object 252A as objects that satisfy the first process characteristics described by the first process specification object 212A. Additionally, the one or more processors 104 can inhibit selection of objects that do not satisfy the first process characteristics described by the first process specification object 212A. For example, the one or more processors 104 can inhibit selection of the Mth equipment object 222C, the first logistics object 232A, the second tooling object 242B, the second personnel object 252B, and the Lth personnel object 252C.

Thus, the linking operation in FIG. 3 enables the one or more processors 104 to update the production system estimates 164 based on linking the first process specification object 212A to the first node data element 154A. For example, the production system estimates 164 are updated to reflect the resources that will be used during the first production task 142A. Additionally, the linking operation in FIG. 3 enables the one or more processors 104 to inhibit linking of objects to the first node data element 154A that are not compatible with the first process specification object 212A.

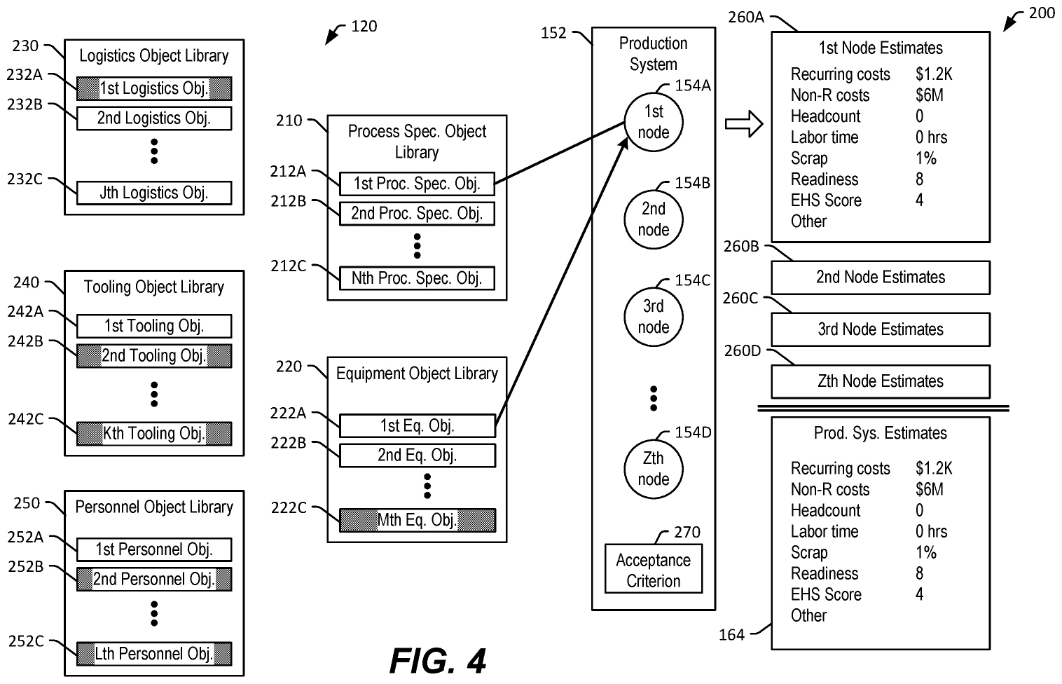

FIG. 4 is a diagram that illustrates linking another object to the first node data element and updating the production system estimates based on the link. For example, in FIG. 4, the first equipment object 222A is linked to the first node data element 154A.

According to linking operation illustrated in FIG. 4 (and with references to FIGS. 1-3), the input interface of the input/output interfaces 108 receives a second input that associates the first production task 142A with the first equipment object 222A. In response to receiving the second input, the one or more processors 104 link the first node data element 154A (e.g., the modeled version of the first production task 142A) to the first equipment object 222A that describes first equipment-related manufacturing process characteristics associated with a first manufacturing device. Additionally, the one or more processors 104 update the first linking data 130A to indicate that the first node data element 154A is linked to the first equipment object 222A.

The first node estimates 260A are updated based on the first equipment object 222A. For example, the first node estimates 260A include a recurring cost of $1,200, a non-recurring cost of $6M, a 1% manufacturing scrap estimate, a manufacturing readiness score of 8, and an EHS score of 4. Because there are no objects linked to the other node data elements 154B-154D, the other corresponding node estimates 260B-260D are null, and the production system estimates 164 are equal to the first node estimates 260A. For example, the production system estimates 164 include a recurring cost of $1,200, a non-recurring cost of $6M, a 1% manufacturing scrap estimate, a manufacturing readiness score of 8, and an EHS score of 4.

The one or more processors 104 can execute the object editor instructions 118 to identify a set of objects that are compatible with objects already associated with the first node 154A (e.g., the first process specification object 212A and the first equipment object 222A). For example, the one or more processors 104 can identify the second logistics object 232B, the Jth logistics object 232C, the first tooling object 242A, and the first personnel object 252A as objects that are compatible with objects already associated with the first node 154A. Additionally, the one or more processors 104 can inhibit selection of objects that are not compatible with objects already associated with the first node 154A. For example, the one or more processors 104 can inhibit selection of the first logistics object 232A, the second tooling object 242B, the Kth tooling object 242C, the second personnel object 252B, and the Lth personnel object 252C.

Thus, the linking operation in FIG. 4 enables the one or more processors 104 to update the production system estimates 164 based on linking the first equipment object 222A to the first node data element 154A. For example, the production system estimates 164 are updated to reflect the resources that will be used during the first production task 142A.

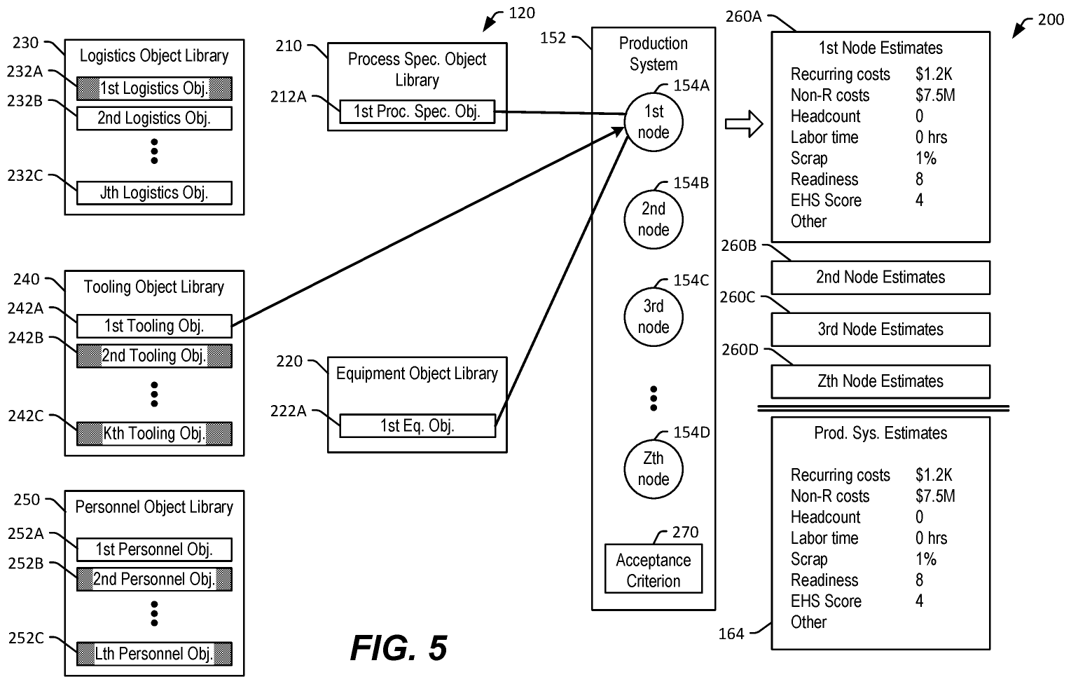

FIG. 5 is a diagram that illustrates linking another object to the first node data element and updating the production system estimates based on the link. For example, in FIG. 5, the first tooling object 242A is linked to the first node data element 154A.

According to linking operation illustrated in FIG. 5 (and with reference to FIGS. 1-4), the input interface of the input/output interfaces 108 receives an input that associates the first production task 142A with the first tooling object 242A. In response to receiving the input, the one or more processors 104 link the first node data element 154A (e.g., the modeled version of the first production task 142A) to the first tooling object 242A that describes tooling-related manufacturing process characteristics. Additionally, the one or more processors 104 update the first linking data 130A to indicate that the first node data element 154A is linked to the first tooling object 242A.

The first node estimates 260A are updated based on the first tooling object 242A. For example, the first node estimates 260A include a recurring cost of $1,200, a non-recurring cost of $7.5M, a 1% manufacturing scrap estimate, a manufacturing readiness score of 8, and an EHS score of 4. Because there are no objects linked to the other node data elements 154B-154D, the other corresponding node estimates 260B-260D are null, and the production system estimates 164 are equal to the first node estimates 260A. For example, the production system estimates 164 include a recurring cost of $1,200, a non-recurring cost of $7.5M, a 1% manufacturing scrap estimate, a manufacturing readiness score of 8, and an EHS score of 4.

The one or more processors 104 can also to identify a set of objects that are compatible with objects already associated with the first node 154A (e.g., the first process specification object 212A, the first equipment object 222A, and the first tooling object 242A). For example, the one or more processors 104 can identify the second logistics object 232B, the Jth logistics object 232C, and the first personnel object 252A as objects that are compatible with objects already associated with the first node 154A. Additionally, the one or more processors 104 can inhibit selection of objects that are not compatible with objects already associated with the first node 154A. For example, the one or more processors 104 can inhibit selection of the first logistics object 232A, the second personnel object 252B, and the Lth personnel object 252C.

Thus, the linking operation in FIG. 5 enables the one or more processors 104 to update the production system estimates 164 based on linking the first tooling object 242A to the first node data element 154A. For example, the production system estimates 164 are updated to reflect the resources that will be used during the first production task 142A.

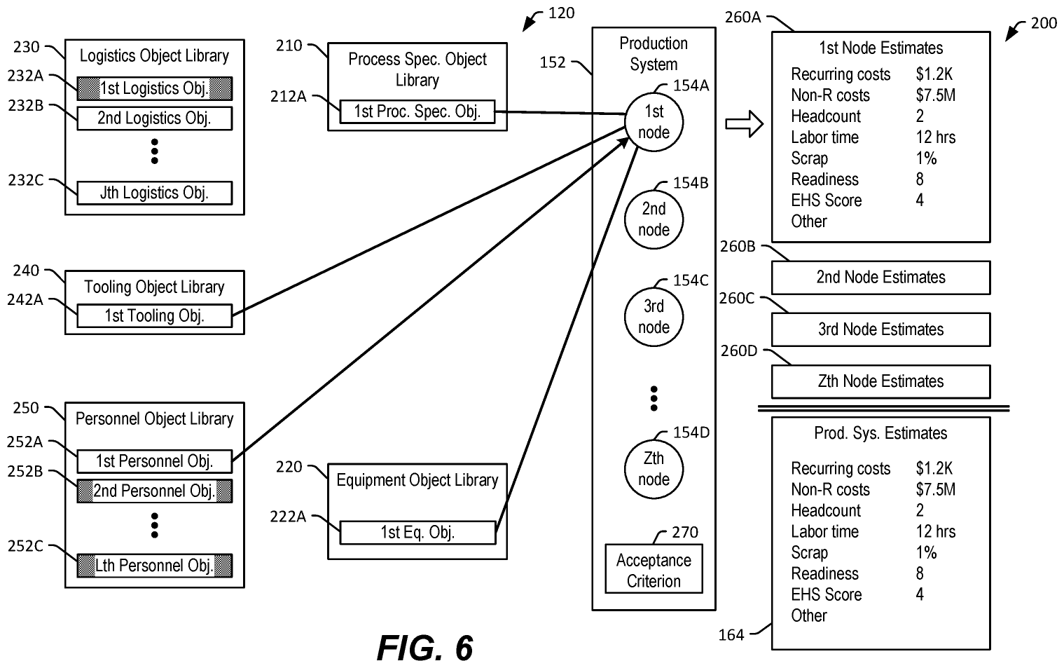

FIG. 6 is a diagram that illustrates linking another object to the first node data element and updating the production system estimates based on the link. For example, in FIG. 6, the first personnel object 252A is linked to the first node data element 154A.

According to linking operation illustrated in FIG. 6 (and with reference to FIGS. 1-5), the input interface of the input/output interfaces 108 receives an input that associates the first production task 142A with the first personnel object 252A. In response to receiving the input, the one or more processors 104 link the first node data element 154A (e.g., the modeled version of the first production task 142A) to the first personnel object 252A that describes tooling-related manufacturing process characteristics. Additionally, the one or more processors 104 update the first linking data 130A to indicate that the first node data element 154A is linked to the first personnel object 252A.

The first node estimates 260A are updated based on the first personnel object 252A. For example, the first node estimates 260A include a recurring cost of $1,200, a non-recurring cost of $7.5M, a headcount of 2, a labor time of 12 hours, a 1% manufacturing scrap estimate, a manufacturing readiness score of 8, and an EHS score of 4. Because there are no objects linked to the other node data elements 154B-154D, the other corresponding node estimates 260B-260D are null, and the production system estimates 164 are equal to the first node estimates 260A. For example, the production system estimates 164 include a recurring cost of $1,200, a non-recurring cost of $7.5M, a headcount of 2, a labor time of 12 hours, a 1% manufacturing scrap estimate, a manufacturing readiness score of 8, and an EHS score of 4.

The one or more processors 104 can also to identify a set of objects that are compatible with objects already associated with the first node 154A (e.g., the first process specification object 212A, the first equipment object 222A, the first tooling object 242A, and the first personnel object 252A). For example, the one or more processors 104 can identify the second logistics object 232B and the Jth logistics object 232C as objects that are compatible with objects already associated with the first node 154A. Additionally, the one or more processors 104 can inhibit selection of objects that are not compatible with objects already associated with the first node 154A. For example, the one or more processors 104 can inhibit selection of the first logistics object 232A.

Thus, the linking operation in FIG. 6 enables the one or more processors 104 to update the production system estimates 164 based on linking the first personnel object 252A to the first node data element 154A. For example, the production system estimates 164 are updated to reflect the resources that will be used during the first production task 142A.

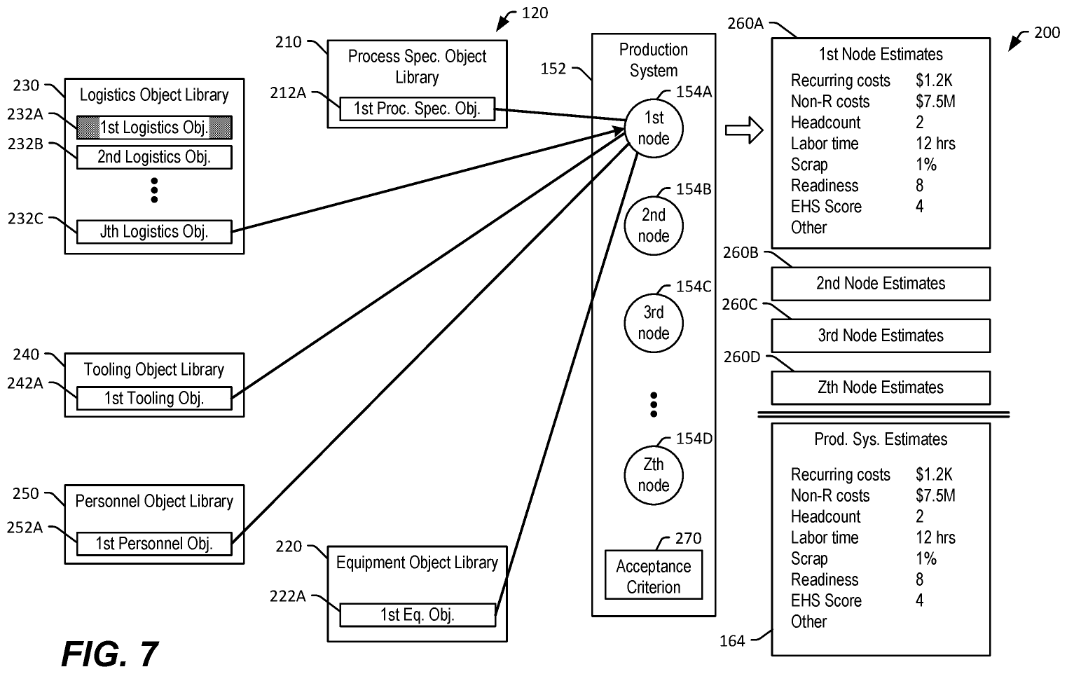

FIG. 7 is a diagram that illustrates linking another object to the first node data element and updating the production system estimates based on the link. For example, in FIG. 7, the Jth logistics object 232C is linked to the first node data element 154A.

According to linking operation illustrated in FIG. 7 (and with reference to FIGS. 1-6), the input interface of the input/output interfaces 108 receives an input that associates the first production task 142A with the Jth logistics object 232C. In response to receiving the input, the one or more processors 104 link the first node data element 154A (e.g., the modeled version of the first production task 142A) to the Jth logistics object 232C that describes a set of logistics-related manufacturing process characteristics. Additionally, the one or more processors 104 update the first linking data 130A to indicate that the first node data element 154A is linked to the Jth logistics object 232C.

The first node estimates 260A are updated based on the Jth logistics object 232C. However, in the scenario described with respect to FIG. 7, linking the Jth logistics object 232C to the first node data element 154A does not change the first node estimates 260A. For example, the first node estimates 260A still include a recurring cost of $1,200, a non-recurring cost of $7.5M, a headcount of 2, a labor time of 12 hours, a 1% manufacturing scrap estimate, a manufacturing readiness score of 8, and an EHS score of 4. Because there are no objects linked to the other node data elements 154B-154D, the other corresponding node estimates 260B-260D are null, and the production system estimates 164 are equal to the first node estimates 260A. For example, the production system estimates 164 include a recurring cost of $1,200, a non-recurring cost of $7.5M, a headcount of 2, a labor time of 12 hours, a 1% manufacturing scrap estimate, a manufacturing readiness score of 8, and an EHS score of 4.

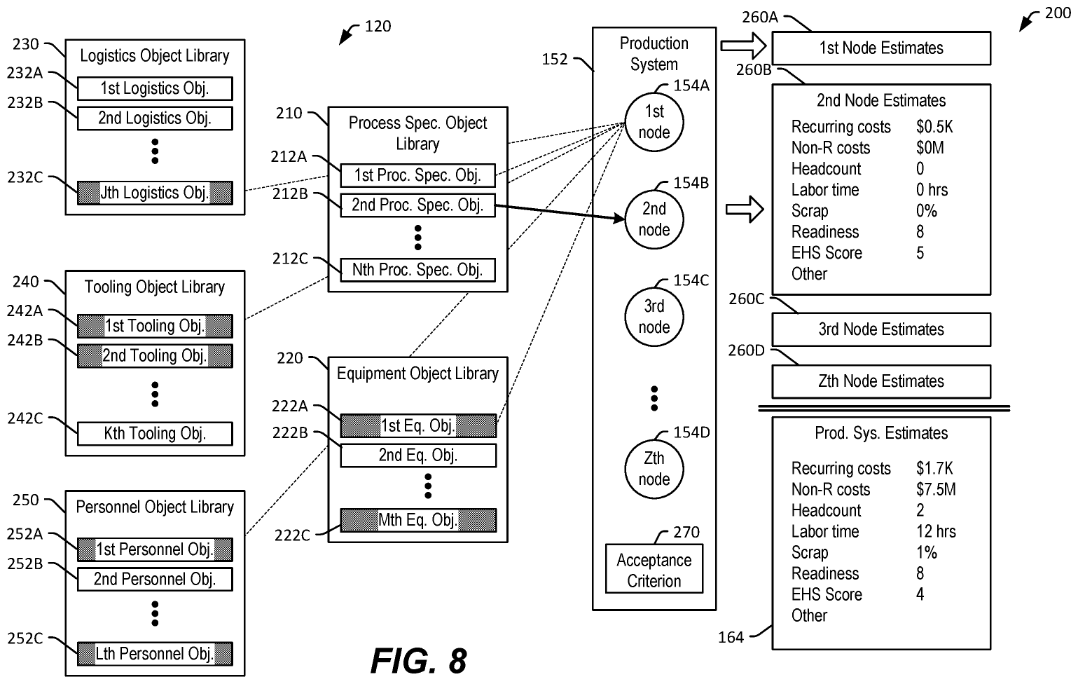

FIG. 8 is a diagram that illustrates linking another object to a second node data element and updating production system estimates based on the link. For example, in FIG. 8, the second process specification object 212B is linked to the second node data element 154B.

According to linking operation illustrated in FIG. 8 (and with reference to FIGS. 1-7), the input interface of the input/output interfaces 108 receives an input that associates the second production task 142B with the second process specification object 212B. In response to receiving the input, the one or more processors 104 link the second node data element 154B (e.g., the modeled version of the second production task 142B) to the second process specification object 212B that describes second process characteristics associated with a second specification. Additionally, the one or more processors 104 generate the second linking data 130B to indicate that the second node data element 154B is linked to the second process specification object 212B.

The second node estimates 260B are generated based on the second process specification object 212B. For example, the second node estimates 260B include a recurring cost of $500, a manufacturing readiness score of 8, and an EHS score of 5. The second node estimates 260B are combined with the first node estimates 260A to update the production system estimates 164. For example, the production system estimates 164 include a recurring cost of $1,700, a non-recurring cost of $7.5M, a headcount of 2, a labor time of 12 hours, a 1% manufacturing scrap estimate, a manufacturing readiness score of 8, and an EHS score of 4. The manufacturing readiness score and the EHS score are updated to reflect the lowest score associated with a node estimate 260A-260D.

The one or more processors 104 can execute the object editor instructions 118 to identify a set of objects that satisfy the second process characteristics described by the second process specification object 212B. For example, the one or more processors 104 can identify the second equipment object 222B, the first logistics object 232A, the second logistics object 232B, the Kth tooling object 242C, and the second personnel object 252B as objects that satisfy the second process characteristics described by the second process specification object 212B. Additionally, the one or more processors 104 can inhibit selection of objects that do not satisfy the second process characteristics described by the second process specification object 212B. For example, the one or more processors 104 can inhibit selection of the first equipment object 222A, the Mth equipment object 222C, the Jth logistics object 232C, the first tooling object 242A, the second tooling object 242B, the first personnel object 252A, and the Lth personnel object 252C.

Thus, the linking operation in FIG. 8 enables the one or more processors 104 to update the production system estimates 164 based on linking the second process specification object 212B to the second node data element 154B. For example, the production system estimates 164 are updated to reflect the resources that will be used during the first production task 142A and during the second production task 142B. Additionally, the linking operation in FIG. 8 enables the one or more processors 104 to inhibit linking of objects to the second node data element 154B that are not compatible with the second process specification object 212B.

Additional objects can be linked to the second node data element 154B in a similar manner as additional objects are linked to the first node data element 154A with respect to FIGS. 4-7. The second node estimates 260B, and thus the production system estimates 164, are updated as different objects are linked to the second node data element 154B.

Although FIGS. 4-8 illustrate one example of an order of operations to link objects of various object libraries to nodes 154 of a production system 152, the operations can be performed in a different order. For example, an equipment object 222 can be linked to a node 154 before a process specification object 212 is linked to the node 154. Further, a node 154 of the production system 152 can be linked to the prior production system 156, the next production system 160, or both, before, during, or after linking nodes 154 of the production system 152 to objects of the object libraries 120. Further, the object editor instructions 118 can be used to identify a set of objects that are compatible with the prior production system 156, the next production system 160, or both.

Further, although FIGS. 4-8 illustrate a particular set of object libraries 120, in other implementations, the object libraries 120 include more object libraries, fewer object libraries, or different object libraries. For example, in some implementations, the equipment objects 222 can be combined with the tooling objects 242 to form a single tooling and equipment object library. In another example, the logistics object library 230 can be divided into two or separate libraries for consumables (e.g., materials used in manufacturing that do not become part of the final product, such as sand paper or cleaners) and raw material (e.g., materials used in manufacturing that do become part of the final product).

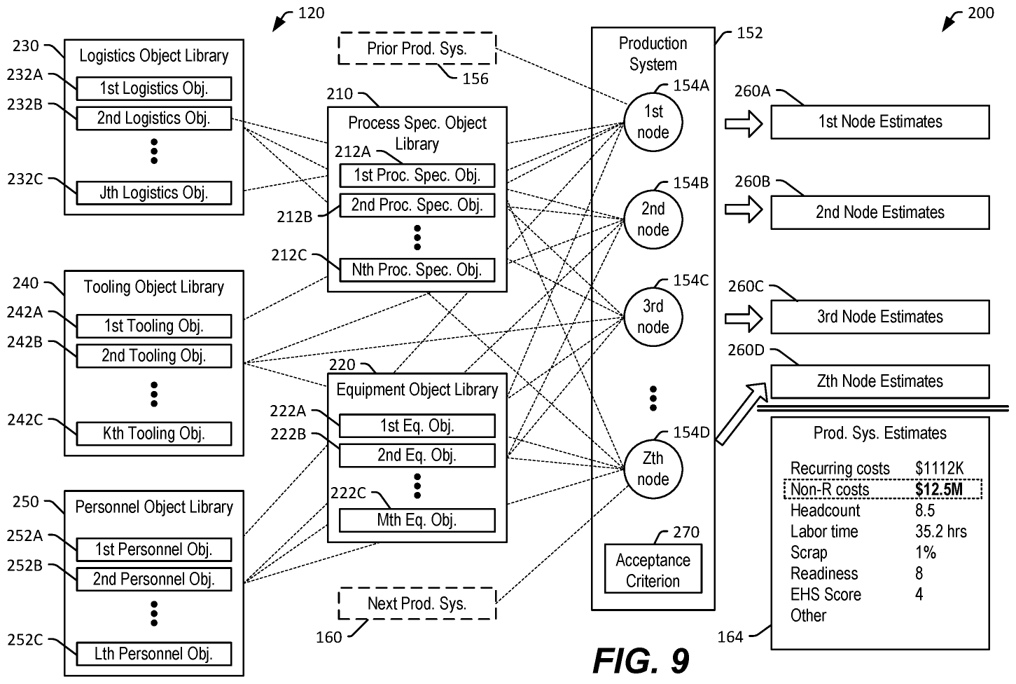

FIG. 9 is a diagram that illustrates a plurality of objects linked to different node data elements of a production system and production system estimates based on the links. For example, in FIG. 9, objects from the object libraries are linked to the first node data element 154A, the second node data element 154B, the third node data element 154C, and the Zth node data element 154D.

Each node estimate 260A-260D associated with the node data elements 154A-154D, respectively, is determined based on the objects 122 linked to the node data elements 154A-154D. The production system estimates 164 are the result of each node estimate 260A-260D. For example, the production system estimates 164 include a recurring cost of $1,112,000, a non-recurring cost of $12.5M, a headcount of 8.5, a labor time of 35.2 hours, a 1% manufacturing scrap estimate, a manufacturing readiness score of 8, and an EHS score of 4. The manufacturing readiness score and the EHS score reflect the lowest score associated with a node estimate 260A-260D.

The one or more processors 104 can compare the production system estimates 164 to the acceptance criterion 270 for the production system 152. The one or more processors 104 can also generate a notification indicating whether the manufacturing process 140 described by the production system 152 is expected to satisfy requirements indicated by the acceptance criterion 270. To illustrate, in FIG. 9, the non-recurring cost estimate is highlighted to indicate that the non-recurring cost estimate does not satisfy a corresponding acceptance criterion 270. A user can examine the node estimates 260 to identify a node 154 associated with high non-recurring costs and link the node (and perhaps one or more other nodes) to one or more objects (e.g., to model one or more somewhat different tasks) to attempt to resolve the failure to satisfy the acceptance criterion 270. Alternately, in some implementations, the user can modify the prior production system 156, the next production system 160, or both, to resolve the failure to satisfy the acceptance criterion 270.

For example, if the production system 152 includes a task for sanding that leads to unacceptable non-recurring costs, the user may modify the prior production system 156 to model a manufacturing process that results in a component that does not need to be sanded. Alternatively, the user may modify the next production system 160 to model a manufacturing process that is compatible with a component that has not been sanded.

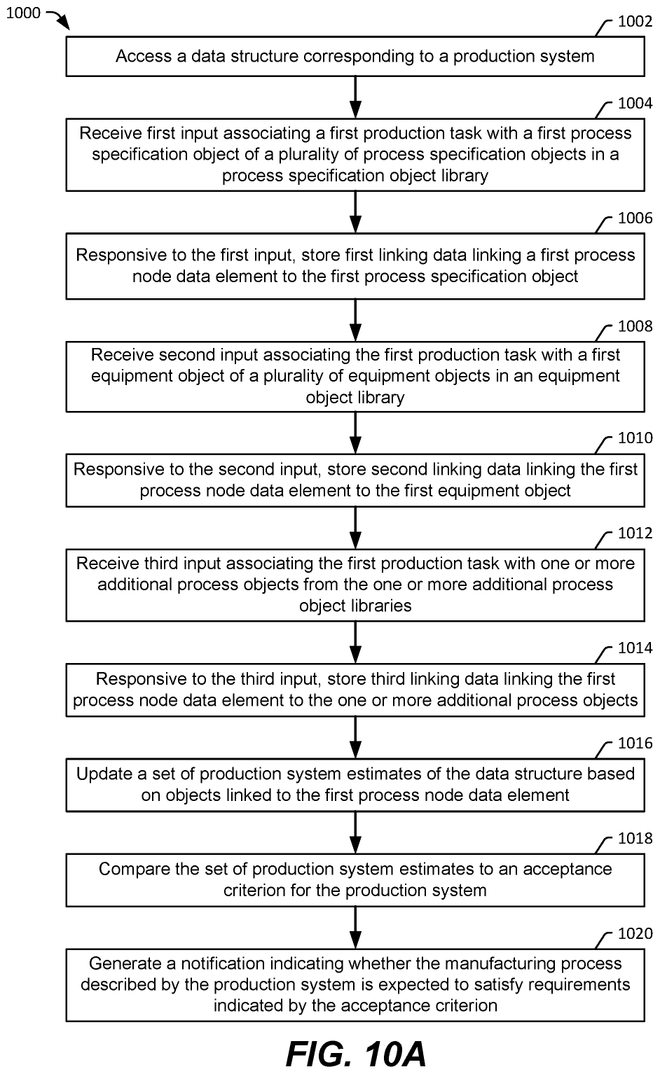

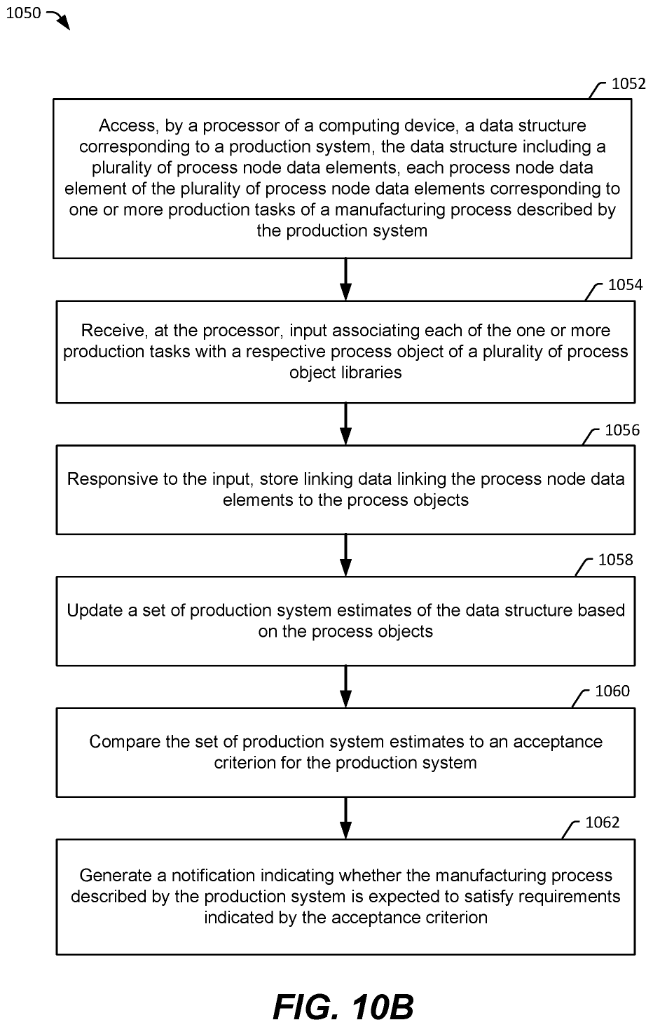

FIG. 10A is a flow chart of an example of a method 1000 of modeling a manufacturing process. The method 1000 may be performed by the computing device 102 of FIG. 1.

The method 1000 includes, at 1002, accessing, by a processor of a computing device, a data structure corresponding to a production system. The data structure includes a plurality of process node data elements, and each process node data element corresponds to one or more production tasks of a manufacturing process described by the production system. For example, the one or more processors 104 access the data structure 126 that corresponds to the production system 152. The data structure 126 includes the process node data elements 128, and each process node data element 128 corresponds to a production task 142 of the manufacturing process 140 described by the production system 152.

The method 1000 includes, at 1004, receiving, at the processor, a first input associating a first production task with a first process specification object of a plurality of process specification objects in a process specification object library. Each process specification object of the plurality of process specification objects describes process characteristics associated with a respective process specification, and the first process specification object describes first process characteristics associated with a first process specification. For example, the one or more processors 104 receive the first input associating the first production task 142A with the first process specification object 212A in the process specification object library 210.

The method 1000 includes, at 1006, responsive to the first input, storing first linking data linking a first process node data element to the first process specification object, where the first process node data element is associated with the first production task. For example, the one or more processors 104 store the first linking data 130A that links the first process node data element 128A to the first process specification object 212A.

The method 1000 includes, at 1008, receiving, at the processor, second input associating the first production task with a first equipment object of a plurality of equipment objects in an equipment object library, where the first equipment object describes first equipment-related manufacturing process characteristics associated with a first manufacturing device. For example, the one or more processors 104 receive the second input associating the first production task 142A with the first equipment object 222A in the equipment object library 220.

The method 1000 includes, at 1010, responsive to the second input, storing second linking data linking the first process node data element to the first equipment object. For example, the one or more processors 104 store the first linking data 130A (e.g., the “second linking data” according to the method 1000) that links the first process node data element 128A to the first equipment object 222A.

The method 1000 includes, at 1012, receiving, at the processor, a third input associating the first production task with one or more additional process objects from the one or more additional process object libraries. Each process object of the one or more additional process objects describes one or more process characteristics. For example, the one or more processors 104 receive the input associating the first production task 142A with the first tooling object 242A from the tooling object library 240, receive the first personnel object 252A from the personnel object library 250, or receive the Jth logistics object 232C from the logistics object library 230.

The method 1000 includes, at 1014, responsive to the third input, storing third linking data linking the first process node data element to the one or more additional process objects. For example, the one or more processors 104 store the first linking data 130A (e.g., the “third linking data” according to the method 1000) that links the first process node data element 128A to the selected object.

The method 1000 includes, at 1016, updating a set of production system estimates of the data structure based on objects linked to the first process node data element. For example, the one or more processors 104 update the production system estimates 164 based on the objects linked to the first process node data element 154A.

The method 1000 includes, at 1018, comparing the set of production system estimates to an acceptance criterion for the production system. For example, the one or more processors 104 compare the production system estimates 164 to the acceptance criterion 270 for the production system 152.

The method 1000 includes, at 1020, generating a notification indicating whether the manufacturing process described by the production system is expected to satisfy requirements indicated by the acceptance criterion. For example, the one or more processors 104 generate a notification indicting whether the manufacturing process 140 described by the production system 152 is expected to satisfy requirements indicated by the acceptance criterion 270.

According to one implementation, the method 1000 includes receiving requirements data for the production system 152 before comparing the set of production system estimates 280 to the acceptance criterion 270. The requirements data indicates a condition of assembly associated with the manufacturing process 140. For example, the condition of assembly indicates input materials for the manufacturing process 140, an expected output product for the manufacturing process 140, or both. The method 1000 includes determining the acceptance criterion 270 for the production system 152 based on the requirements data. The method 1000 also includes associating the acceptance criterion 270 with the data structure 126.

According to one implementation, the method 1000 includes, responsive to receiving the first input, identifying a set of objects 122 of a plurality of process object libraries 120 that satisfy the first process characteristics. The method 1000 also includes inhibiting selection of objects of the plurality of process object libraries 120 that do not satisfy the first process characteristics. According to one implementation, inhibiting the selection prevents the second input from associating the first production task 142A with a second equipment object 222B that does not satisfy the first process characteristics. According to another implementation, inhibiting the selection prevents the third input from associating the first production task 142A with a particular logistics object 232 that does not satisfy the first process characteristics. According to another implementation, inhibiting the selection prevents the third input from associating the first production task 142A with a particular tooling object 242 that does not satisfy the first process characteristics. According to another implementation, inhibiting the selection prevents the third input from associating the first production task 142A with a particular personnel object 252 that does not satisfy the first process characteristics.

According to one implementation, the method 1000 includes linking each other process node data element 130B-130D of the plurality of process node data elements 128 to a respective set of objects to describe an entirety of the manufacturing process 140. Each of the respective sets of objects includes two or more of a process specification object 212 from the process specification object library 210, an equipment object 222 from the equipment object library 220, a personnel object 252 from a personnel object library 250, a tooling object 242 from a tooling object library 240, or a logistics object 232 from a logistics object library 230.

According to one implementation, the method 1000 includes modeling a change to the manufacturing process 140 by modifying or removing a link between a process node data element 128 and an object, and updating the set of production system estimates 164 after modifying or removing the link. For example, if the production system estimates 164 do not satisfy the acceptance criterion 270, the one or more processors 104 can modify or remove a link to ensure compliance. According to one implementation, the method 1000 includes linking an input node data element of the production system 152 to an output node data element of a prior manufacturing process 144. For example, the first node data element 154 can be linked to the last node data element 158 of the prior production system 156. According to another implementation, the method 1000 includes modeling a change to the manufacturing process 140 by adding node data element 154 (e.g., a production node) to the production system 152, removing a node data element 154 from the production system 152, or dividing a node data element 154 into two or more node data elements 154.

FIG. 10B is a flow chart of an example of a method 1050 of modeling a manufacturing process. The method 1050 may be performed by the computing device 102 of FIG. 1.

The method 1050 includes accessing, by a processor of a computing device, a data structure corresponding to a production system, at 1052. The data structure includes a plurality of process node data elements. Each process node data element of the plurality of process node data elements corresponds to one or more production tasks of a manufacturing process described by the production system. For example, the one or more processors 104 access the data structure 126 corresponding to the production system 152. The data structure 126 includes the plurality of process node data elements 128, and each process node data element 128 of the plurality of process node data elements 128 corresponds to the production tasks 142 of the manufacturing process 140 described by the production system 152.

The method 1050 also includes receiving, at the processor, input associating each of the one or more production tasks with a respective process object of a plurality of process object libraries, at 1054. For example, the one or more processors 104 receive input associated each of the one or more production tasks 142 with a respective process object 122 of the plurality of process object libraries 120.

The method 1050 also includes responsive to the input, storing linking data linking the process node data elements to the process objects, at 1056. For example, the one or more processors 104 store linking data that links the process node data elements 128 to the process objects 122.

The method 1050 also includes updating a set of production system estimates of the data structure based on the process objects, at 1058. For example, the one or more processors update the set of production system estimates 164 of the data structure 126 based on the process objects 122.

The method 1050 also includes comparing the set of production system estimates to an acceptance criterion for the production system, at 1060. For example, the one or more processors 104 compare the set of production system estimates 164 to the acceptance criterion 270 for the production system 152.

The method 1050 also includes generating a notification indicating whether the manufacturing process described by the production system is expected to satisfy requirements indicated by the acceptance criterion, at 1062. For example, the one or more processors 104 generate a notification indicating whether the manufacturing process 140 described by the production system 152 is expected to satisfy requirements indicated by the acceptance criterion 270.

According to one implementation, the method 1050 also includes, in response to a determination that the set of production system estimates 164 fails to satisfy the acceptance criterion 270, iteratively updating the set of production system estimates 164 until the set of production system estimates 164 satisfy the acceptance criterion 270. Updating the set of production system estimates 164 includes receiving an additional input that associates at least one production task 142 of the one or more production tasks 142 with a different process object 122 of the plurality of process object libraries 120. Updating the set of production system estimates 164 also includes, responsive to the additional input, storing linking data 130 that links the process node data elements 128 to the process objects 122. The set of production system estimates 164 are updated based on the process objects 122.

The methods 1000, 1050 enable the computing device 102 to efficiently generate the production system estimates 164 for the manufacturing process 140 and compare the production system estimates 164 to acceptance criteria. For example, the production system estimates 164 can be compared to criteria for technical readiness, environmental and safety, costs, input and/or output materials, and so forth. The object libraries 120 provide a reusable mechanism to model many different manufacturing processes, such as the manufacturing process 140, in a manner that is resource efficient. For example, using reusable object libraries 120 to generate the data structure 126 means that the content of the libraries 120 does not need to be replicated each time a new manufacturing process is modeled, or when a change to the manufacturing process 140 is proposed. Thus, using the object libraries 120 and linking data 130 uses less memory than a system in which the content of the objects 122 is replicated for each new or modified manufacturing system.

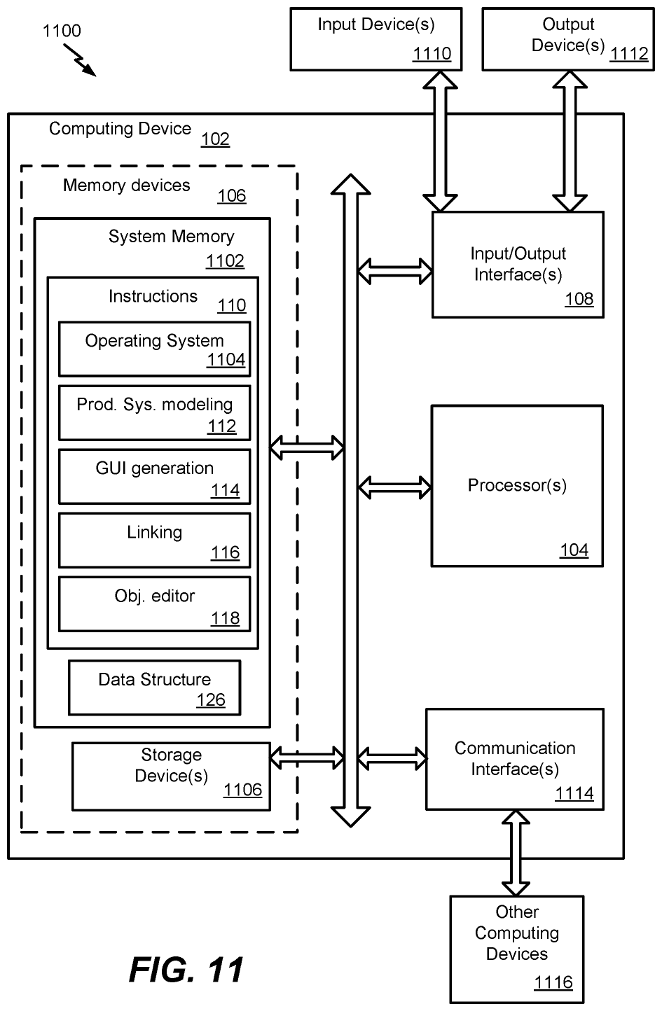

FIG. 11 is a block diagram illustrating aspects of an example of a computing system configured to perform operations to model a manufacturing process. FIG. 11 illustrates a computing environment 1100 including the computing device 102 configured to support embodiments of computer-implemented methods and computer-executable program instructions (or code) according to the present disclosure. For example, the computing device 102, or portions thereof, may execute instructions to initiate, perform, or control modeling of the manufacturing process 140. To illustrate, the computing device 102, or portions thereof, may execute the instructions 110 to perform the modeling of the manufacturing process 140. The computing device 102, or portions thereof, may further execute instructions to perform any of the operations or methods described herein, such as the operations and/or method described with reference to FIGS. 2-10.

The computing device 102 includes the one or more processors 104. The one or more processors 104 communicate with the memory devices 106, including a system memory 1102 and one or more storage devices 1106. The computing device 102 also includes the one or more input/output interfaces 108, one or more communications interfaces 1114, or a combination thereof. The one or more of the memory devices 106 can include a remote storage device (e.g., a data repository) in which case the one or more processors 104 can communicate with the one or more other computing devices 1116 via the communications interfaces 1114 or another network interface.

The memory devices 106 include volatile memory devices (e.g., random access memory (RAM) devices), nonvolatile memory devices (e.g., read-only memory (ROM) devices, programmable read-only memory, and flash memory), or both. According to one implementation, a memory device 106 is a non-transitory computer readable storage device. The memory devices 106 can include an operating system 1104, which includes a basic input/output system for booting the computing device 102 as well as a full operating system to enable the computing device 102 to interact with users, other programs, and other devices. The memory devices 106 can also include one or more applications that are executable by the one or more processors 104. For example, the one or more applications can include performing or controlling the modeling of the manufacturing process 140.

The storage devices 1106 can include nonvolatile storage devices, such as magnetic disks, optical disks, or flash memory devices. The storage devices 1106 can include both removable and non-removable memory devices. The storage devices 1106 can be configured to store an operating system, images of operating systems, applications, and program data. In a particular example, the memory devices 106, the storage devices 1106, or both, include tangible computer-readable media.

The one or more processors 104 communicate with one or more input devices 1110, one or more output devices 1112, or both, via the one or more input/output interfaces 108 to facilitate user interaction. The input/output interfaces 108 can include serial interfaces (e.g., universal serial bus (USB) interfaces or Institute of Electrical and Electronics Engineers (IEEE) 1394 interfaces), parallel interfaces, display adapters, audio adapters, and other interfaces. The input devices 1110 and output devices 1112 can include keyboards, pointing devices, displays, speakers, microphones, touch screens, and other devices. The one or more processors 104 can detect interaction events based on user input received via the input/output interfaces 108. Additionally, the one or more processors 104 can send a display to a display device via the input/output interfaces 108.

The one or more processors 104 can communicate with (or send signals to) one or more other computing devices 1116 via the communications interface 1114. The communications interface 1114 can include one or more wired interfaces (e.g., Ethernet interfaces), one or more wireless interfaces that comply with an IEEE 802.11 communication protocol, other wireless interfaces, optical interfaces, or other network interfaces. The one or more other computing devices 1116 can also include host computers, servers, workstations, and other computing devices.

In conjunction with the described examples, the memory devices 106 can include a computer readable storage device for storing instructions that are executable by a processor (e.g., the one or more processors 104) to cause the processor to perform operations including accessing a data structure corresponding to a production system. The data structure includes a plurality of process node data elements, where each process node data element corresponds to one or more production tasks of a manufacturing process described by the production system. The operations also include receiving first input associating a first production task with a first process specification object of a plurality of process specification objects in a process specification object library. Each process specification object of the plurality of process specification objects describes process characteristics associated with a respective process specification, and the first process specification object describes first process characteristics associated with a first process specification. The operations further include, responsive to the first input, storing first linking data linking a first process node data element to the first process specification object, where the first process node data element is associated with the first production task. The operations also include receiving second input associating the first production task with a first equipment object of a plurality of equipment objects in an equipment object library, where the first equipment object describes first equipment-related manufacturing process characteristics associated with a first manufacturing device (e.g., a respective manufacturing device). The operations also include, responsive to the second input, storing second linking data linking the first process node data element to the first equipment object. The operations include receiving third input associating the first production task with one or more additional process objects from one or more additional process object libraries. Each process object of the one or more additional process objects describes one or more process characteristics. The operations further include, responsive to the third input, storing third linking data linking the first process node data element to the one or more additional process objects. The operations also include updating a set of production system estimates of the data structure based on objects linked to the first process node data element and comparing the set of production system estimates to an acceptance criterion for the production system. The operations also include generating a notification indicating whether the manufacturing process described by the production system is expected to satisfy requirements indicated by the acceptance criterion.

The illustrations of the examples described herein are intended to provide a general understanding of the structure of the various implementations. The illustrations are not intended to serve as a complete description of all of the elements and features of apparatus and systems that utilize the structures or methods described herein. Many other implementations may be apparent to those of skill in the art upon reviewing the disclosure. Other implementations may be utilized and derived from the disclosure, such that structural and logical substitutions and changes may be made without departing from the scope of the disclosure. For example, method operations may be performed in a different order than shown in the figures or one or more method operations may be omitted. Accordingly, the disclosure and the figures are to be regarded as illustrative rather than restrictive.

Moreover, although specific examples have been illustrated and described herein, it should be appreciated that any subsequent arrangement designed to achieve the same or similar results may be substituted for the specific implementations shown. This disclosure is intended to cover any and all subsequent adaptations or variations of various implementations. Combinations of the above implementations, and other implementations not specifically described herein, will be apparent to those of skill in the art upon reviewing the description.

The Abstract of the Disclosure is submitted with the understanding that it will not be used to interpret or limit the scope or meaning of the claims. In addition, in the foregoing Detailed Description, various features may be grouped together or described in a single implementation for the purpose of streamlining the disclosure. Examples described above illustrate, but do not limit, the disclosure. It should also be understood that numerous modifications and variations are possible in accordance with the principles of the present disclosure. As the following claims reflect, the claimed subject matter may be directed to less than all of the features of any of the disclosed examples. Accordingly, the scope of the disclosure is defined by the following claims and their equivalents.

What is claimed is:

1. A computing device comprising:
one or more processors;
one or more memory devices, the one or more memory device storing:
a data structure of a production system, the data structure including a plurality of process node data elements, each process node data element of the plurality of process node data elements corresponding to one or more production tasks of a manufacturing process described by the production system;
a plurality of process object libraries, including:
a process specification object library including a plurality of process specification objects, each process specification object of the plurality of process specification objects describing characteristics associated with a respective process specification;
an equipment object library including a plurality of equipment objects, each equipment object of the plurality of equipment objects describing equipment-related characteristics associated with a respective manufacturing equipment item; and
one or more additional object libraries, each of the one or more additional object libraries including one or more additional objects; and
instructions that are executable by the one or more processors to cause the one or more processors to perform operations comprising:
receiving a first input associating a first production task with a first process specification object of the plurality of process specification objects, the first process specification object describing first process characteristics associated with a first process specification;
responsive to the first input, storing first linking data linking a first process node data element of the plurality of process node data elements to the first process specification object, the first process node data element associated with the first production task;
receiving a second input associating the first production task with a first equipment object of the plurality of equipment objects,
the first equipment object describing first equipment-related manufacturing process characteristics associated with a first manufacturing device;
responsive to the second input, storing second linking data linking the first process node data element to the first equipment object;
receiving a third input associating the first production task with one or more additional objects from the one or more additional object libraries, each process object of the one or more additional objects describing one or more process characteristics;
responsive to the third input, storing third linking data linking the first process node data element to the one or more additional objects;
updating a set of production system estimates associated with the manufacturing process based on objects linked to the first process node data element;
comparing the set of production system estimates to an acceptance criterion for the production system; and
generating a notification indicating whether the manufacturing process described by the production system is expected to satisfy requirements indicated by the acceptance criterion.

2. The computing device of claim 1, wherein the operations further comprise, before comparing the set of production system estimates to the acceptance criterion:
receiving requirements data for the production system, the requirements data indicating a condition of assembly associated with the manufacturing process, the condition of assembly indicating input materials for the manufacturing process and an expected output product for the manufacturing process;
determining the acceptance criterion for the production system based on the requirements data; and
associating the acceptance criterion with the data structure.

3. The computing device of claim 1, wherein the operations further comprise, responsive to receiving the first input:
identifying a set of objects of a plurality of process object libraries that satisfy the first process characteristics; and
inhibiting selection of objects of the plurality of process object libraries that do not satisfy the first process characteristics.

4. The computing device of claim 3, wherein each equipment object of the plurality of equipment objects describes equipment-related manufacturing process characteristics associated with a respective manufacturing device, and wherein the inhibiting the selection prevents the second input from associating the first production task with a second equipment object that does not satisfy the first process characteristics.

5. The computing device of claim 3, wherein the one or more additional object libraries include a logistics object library, the logistics object library including a plurality of logistics objects, each logistics object of the plurality of logistics objects describing a set of logistics-related manufacturing process characteristics, and wherein the inhibiting the selection prevents the third input from associating the first production task with a particular logistics object that does not satisfy the first process characteristics.

6. The computing device of claim 3, wherein the one or more additional object libraries include a tooling object library, the tooling object library including a plurality of tooling objects, each tooling object of the plurality of tooling objects describing a set of tooling-related manufacturing process characteristics, and wherein the inhibiting the selection prevents the third input from associating the first production task with a particular tooling object that does not satisfy the first process characteristics.

7. The computing device of claim 3, wherein the one or more additional object libraries include a personnel object library, the personnel object library including a plurality of personnel objects, each personnel object of the plurality of personnel objects describing at set of personnel-related manufacturing process characteristics, and wherein the inhibiting the selection prevents the third input from associating the first production task with a particular personnel object that does not satisfy the first process characteristics.

8. The computing device of claim 1, wherein the operations further comprise linking each other process node data element of the plurality of process node data elements to a respective set of objects to describe an entirety of the manufacturing process, each of the respective sets of objects including two or more of a process specification object from the process specification object library, an equipment object from the equipment object library, a personnel object from a personnel object library, a tooling object from a tooling object library, or a logistics object from a logistics object library.

9. The computing device of claim 8, wherein the plurality of process node data elements are linked according to a precedence order, a criteria-driven branching order, a parallel branching order, a criteria-driven merge order, a parallel merge order, a repeated operations order, or a combination thereof.

10. The computing device of claim 8, wherein the operations further comprise modeling a change to the manufacturing process by:
modifying or removing a link between a process node data element and an object; and
after modifying or removing the link, updating the set of production system estimates.

11. The computing device of claim 1, wherein the operations further comprise linking an input node data element of the production system to an output node data element of a prior manufacturing process.

12. A method comprising:
accessing, by a processor of a computing device, a data structure corresponding to a production system, the data structure including a plurality of process node data elements, each process node data element of the plurality of process node data elements corresponding to one or more production tasks of a manufacturing process described by the production system;
receiving, at the processor, a first input associating a first production task with a first process specification object of a plurality of process specification objects in a process specification object library, each process specification object of the plurality of process specification objects describing process characteristics associated with a respective process specification and the first process specification object describing first process characteristics associated with a first process specification;
responsive to the first input, storing first linking data linking a first process node data element to the first process specification object, the first process node data element associated with the first production task;
receiving, at the processor, a second input associating the first production task with a first equipment object of a plurality of equipment objects in an equipment object library, the first equipment object describing first equipment-related manufacturing process characteristics associated with a first manufacturing device;
responsive to the second input, storing second linking data linking the first process node data element to the first equipment object;
receiving, at the processor, a third input associating the first production task with one or more additional objects from one or more additional object libraries, each process object of the one or more additional objects describing one or more process characteristics;
responsive to the third input, storing third linking data linking the first process node data element to the one or more additional objects;
updating a set of production system estimates of the data structure based on objects linked to the first process node data element;
comparing the set of production system estimates to an acceptance criterion for the production system; and
generating a notification indicating whether the manufacturing process described by the production system is expected to satisfy requirements indicated by the acceptance criterion.

13. The method of claim 12, further comprising, before comparing the set of production system estimates to the acceptance criterion:
receiving, at the processor, requirements data for the production system;
determining, by the processor, the acceptance criterion for the production system based on the requirements data; and
associating the acceptance criterion with the data structure.

14. The method of claim 12, further comprising, responsive to receiving the first input:
identifying a set of objects of a plurality of process object libraries that satisfy the first process characteristics; and
inhibiting selection of objects of the plurality of process object libraries that do not satisfy the first process characteristics.

15. The method of claim 14, wherein the equipment object library includes a plurality of equipment objects, each equipment object of the plurality of equipment objects describing equipment-related manufacturing process characteristics associated with a respective manufacturing device, and wherein the inhibiting the selection prevents the second input from associating the first production task with a second equipment object that does not satisfy the first process characteristics.

16. The method of claim 14, wherein the one or more additional object libraries include a logistics object library, the logistics object library including a plurality of logistics objects, each logistics object of the plurality of logistics objects describing a set of logistics-related manufacturing process characteristics, and wherein the inhibiting the selection prevents the third input from associating the first production task with a particular logistics object that does not satisfy the first process characteristics.

17. The method of claim 14, wherein the one or more additional object libraries include a tooling object library, the tooling object library including a plurality of tooling objects, each tooling object of the plurality of tooling objects describing a set of tooling-related manufacturing process characteristics, and wherein the inhibiting the selection prevents the third input from associating the first production task with a particular tooling object that does not satisfy the first process characteristics.

18. The method of claim 14, wherein the one or more additional object libraries include a personnel object library, the personnel object library including a plurality of personnel objects, each personnel object of the plurality of personnel objects describing at set of personnel-related manufacturing process characteristics, and wherein the inhibiting the selection prevents the third input from associating the first production task with a particular personnel object that does not satisfy the first process characteristics.

19. The method of claim 14, further comprising linking each other process node of the plurality of process node data elements to a respective set of objects to describe an entirety of the manufacturing process, each of the respective sets of objects including two or more of a process specification object from the process specification object library, an equipment object from the equipment object library, a personnel object from a personnel object library, a tooling object from a tooling object library, or a logistics object from a logistics object library.

20. The method of claim 19, wherein the plurality of process node data elements are linked according to a precedence order, a criteria-driven branching order, a parallel branching order, a criteria-driven merge order, a parallel merge order, a repeated operations order, or a combination thereof.

21. The method of claim 19, further comprising modeling a change to the manufacturing process by:
modifying or removing a link between a process node data element and an object; and
after modifying or removing the link, updating the set of production system estimates.

22. The method of claim 14, wherein:
the set of production system estimates includes an estimated one-time cost of the manufacturing process and the acceptance criterion includes a one-time cost threshold,
the set of production system estimates includes an estimated recurring cost of the manufacturing process and the acceptance criterion includes a recurring cost threshold,
the set of production system estimates includes an environmental, health, and safety (EHS) score and the acceptance criterion includes an EHS score threshold,
the set of production system estimates includes a manufacturing readiness score and the acceptance criterion includes a manufacturing readiness score threshold,
the set of production system estimates includes a manufacturing scrap estimate and the acceptance criterion includes a manufacturing scrap threshold,
the set of production system estimates includes a headcount projection and the acceptance criterion includes a headcount threshold, or
a combination thereof.

23. A non-transitory computer readable storage device storing instructions that are executable by a processor to cause the processor to perform operations comprising:
accessing a data structure corresponding to a production system, the data structure including a plurality of process node data elements, each process node data element of the plurality of process node data elements corresponding to one or more production tasks of a manufacturing process described by the production system;
receiving first input associating a first production task with a first process specification object of a plurality of process specification objects in a process specification object library, each process specification object of the plurality of process specification objects describing process characteristics associated with a respective process specification and the first process specification object describing first process characteristics associated with a first process specification;
responsive to the first input, storing first linking data linking a first process node data element to the first process specification object, the first process node data element associated with the first production task;
receiving second input associating the first production task with a first equipment object of a plurality of equipment objects in an equipment object library, the first equipment object describing first equipment-related manufacturing process characteristics associated with a first manufacturing device;
responsive to the second input, storing second linking data linking the first process node data element to the first equipment object;
receiving third input associating the first production task with one or more additional objects from one or more additional object libraries, each process object of the one or more additional objects describing one or more process characteristics;
responsive to the third input, storing third linking data linking the first process node data element to the one or more additional objects;
updating a set of production system estimates of the data structure based on objects linked to the first process node data element;
comparing the set of production system estimates to an acceptance criterion for the production system; and
generating a notification indicating whether the manufacturing process described by the production system is expected to satisfy requirements indicated by the acceptance criterion.

24. A method comprising:
accessing, by a processor of a computing device, a data structure corresponding to a production system, the data structure including a plurality of process node data elements, each process node data element of the plurality of process node data elements corresponding to one or more production tasks of a manufacturing process described by the production system;
receiving, at the processor, input associating each of the one or more production tasks with a respective process object of a plurality of process object libraries;
responsive to the input, storing linking data linking the process node data elements to the process objects;
updating a set of production system estimates of the data structure based on the process objects;
comparing the set of production system estimates to an acceptance criterion for the production system; and
generating a notification indicating whether the manufacturing process described by the production system is expected to satisfy requirements indicated by the acceptance criterion.

25. The method of claim 24, further comprising, in response to a determination that the set of production system estimates fails to satisfy the acceptance criterion:
iteratively updating the set of production system estimates until the set of production system estimates satisfy the acceptance criterion, wherein iteratively updating the set of production system estimates comprises:
receiving an additional input that associates at least one production task of the one or more production tasks with a different process object of the plurality of process object libraries;
responsive to the additional input, storing linking data linking the process node data elements to the process objects; and
updating the set of production system estimates of the data structure based on the process objects.
